(19) United States
(12) Patent Application Publication
(10) Pub. No.: US 2022/0228819 A1
(43) Pub. Date: Jul. 21, 2022

(54) HEAT EXCHANGER MEMBER, HEAT EXCHANGER, AND COOLING SYSTEM

(71) Applicant: YAMAICHI SPECIAL STEEL CO., LTD., Nagoya-shi, Aichi (JP)

(72) Inventors: Hideharu TAJIMA, Nagoya-shi, Aichi (JP); Motoki TAKAGAWA, Nagoya-shi, Aichi (JP); Tomoko SUZUKI, Nagoya-shi, Aichi (JP)

(73) Assignee: YAMAICHI SPECIAL STEEL CO., LTD., Nagoya-shi, Aichi (JP)

(21) Appl. No.: 17/612,312

(22) PCT Filed: Mar. 2, 2021
(86) PCT No.: PCT/JP2021/007930

§ 371 Date: Nov. 18, 2021

(30) Foreign Application Priority Data
Mar. 17, 2020 (JP) 2020-046008

(51) Int. Cl. F28F 13/18

(52) U.S. Cl. CPC F28F 13/187

(57) ABSTRACT

A heat exchanger member, a heat exchanger, a heat exchanger, and a cooling system that are highly efficient are realized by providing, to a surface of a metal in contact with a refrigerant, of a heat exchanger used for a cooling unit and a heat dissipation unit, characteristics not found in the metal itself with a coating film excelling in thermal conductivity and excelling in wettability with the refrigerant.

A heat exchanger member made of metal having a surface that comes into contact with a refrigerant when a heat exchanger is operated includes a metal oxide film provided on the surface, having protrusions, and containing crystalline carbon. An average spacing between apexes of the protrusions is greater than or equal to 20 nm and less than or equal to 80 nm, an average value of the heights of the apexes of adjacent protrusions is greater than or equal to 10 nm and less than or equal to 70 nm, and an aspect ratio which is a value obtained by dividing the average height by the average spacing is less than one.

### TECHNICAL FIELD

The present invention relates to a heat exchanger member using a refrigerant having a cooling effect compared to water, in which a metal surface is provided with characteristics other than the characteristics inherent to the metal, and a device including the member.

### BACKGROUND ART

In a cooling system using a refrigerant, the refrigerant circulates in the system during operation, an object is cooled by vaporization of the refrigerant flowing in a heat exchanger in a cooling unit, and the refrigerant is coded and liquefied by outside air or the like in the heat exchanger of a heat dissipation unit. In the above cooling system, the size of the system which may impose a limitation in the installation and the energy consumption of the pump for circulating the refrigerant are determined by the efficiency of releasing heat to the outside in the heat exchanger of the heat dissipation unit, to liquefy the refrigerant (hereinafter, referred to as liquefaction efficiency), the efficiency of vaporizing the refrigerant in the heat exchanger of the cooling unit to take away heat (hereinafter, referred to as vaporization efficiency), and the pressure loss of the refrigerant flowing through the tube.

On the other hand, in recent years, the amount of information processed by semiconductor devices and the processing speed have been increasing, and high integration as a countermeasure therefor causes a limitation .in the installation of a corresponding cooling system and increases power consumption.

Therefore, for the freedom in the installation of a cooling system and for the reduction of the energy consumption, techniques related to liquefaction efficiency, vaporization efficiency, and pressure loss reduction have been studied. Such a technique is disclosed in, for example, Patent Literature 1.

Patent Literature 1 describes a method of enhancing vaporization efficiency of a cooling unit and liquefaction efficiency of a heat dissipation unit by adding a gas-liquid separating unit in a cooling system.

### CITATIONS LIST

### Patent Literature

Patent Literature 1: JP 2004-190928 A

### SUMMAPY OF INVENTION

### Technical Problems

However, in the technique of Patent Literature 1, it is necessary to separately add a gas-liquid separating unit to the cooling system, and there is a problem that the installation of the cooling system is limited and the cost is greatly increased.

The present invention has been made in view of the above problems, and an object of the present invention is to provide a heat exchanger member, a heat exchanger, and a cooling system that are highly efficient by providing, to a surface of a metal in contact with a refrigerant of a heat exchanger used for a cooling unit and a heat dissipation unit, characteristics not found in the metal itself with a coating film excelling in thermal conductivity and excelling in wettability with the refrigerant.

### Solutions to Problems

In order to solve the above problems, a heat exchanger member of the present invention is a heat exchanger member made of metal and having a surface that comes into contact with a refrigerant when a heat exchanger formed by the heat exchanger member is operated. The heat exchanger member includes a metal oxide film provided on the surface, having protrusions, and containing crystalline carbon. An average spacing between apexes of the protrusions is greater than or equal to 20 nm and less than or equal to 80 nm, an average value of the heights of the apexes of adjacent protrusions is greater than or equal to 10 nm and less than or equal to 70 nm, and an aspect ratio which is a value obtained by dividing the average height by the average spacing is less than one.

### Advantageous Effects of Invention

The present invention has an effect that a function of enhancing liquefaction and vaporization efficiency of a heat exchanger can be added to a heat exchanger member.

### BRIEF DESCRIPTION OF DRAWINGS

FIG. 1 is a schematic view illustrating a semiconductor cooling system using a heat exchanger member according to a first embodiment of the present invention.

FIG. 2 is a view illustrating a heat exchanger member according to the first embodiment of the present invention.

FIG. 3 is a schematic view illustrating a cross section taken along line a-a in FIG. 2.

FIG. 4 is an AFM observation result of a refrigerant contact surface of the heat exchanger member according to the first embodiment of the present invention.

FIG. 5 is a diagram illustrating equipment for manufacturing the first embodiment of the present invention.

FIG. 6 is a diagram illustrating a time chart of a load electrolysis density for manufacturing the first embodiment of the present invention.

FIG. 7 is a view showing a liquefaction test of the first embodiment of the present invention.

FIG. 8 is an SEM perspective view of the first embodiment of the present invention.

FIG. 9 is an SEM perspective view cf a comparative example with respect to the first embodiment of the present invention.

FIG. 10 is a view illustrating a heat exchanger member according to a second embodiment of the present invention.

FIG. 11 is a schematic view illustrating a cross section taken along line a-a in FIG. 10.

FIG. 12 is an AFM observation result of a refrigerant contact surface of the heat exchanger member according to the second embodiment of the present invention.

FIG. 13 is a view illustrating a facility for manufacturing the second embodiment of the present invention.

FIG. 14 is a diagram illustrating a time chart of a load electrolysis density for manufacturing the second embodiment of the present invention.

FIG. 15 is a view showing a cooling test of the second embodiment of the present invention.

FIG. 16 is a SEM perspective view of the second embodiment of the present invention.

FIG. 17 is a SEM perspective view of a comparative example with respect to the second embodiment of the present invention.

### DESCRIPTION OF EMBODIMENT

### First Embodiment

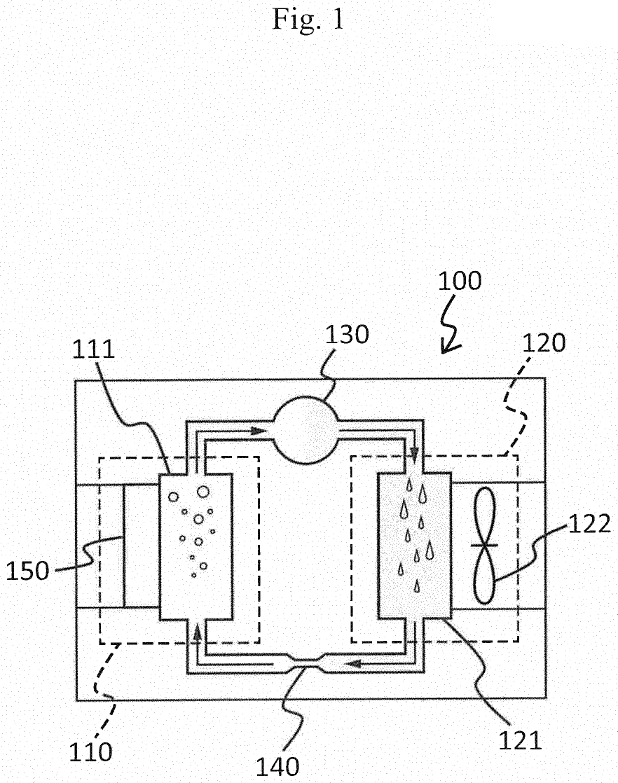

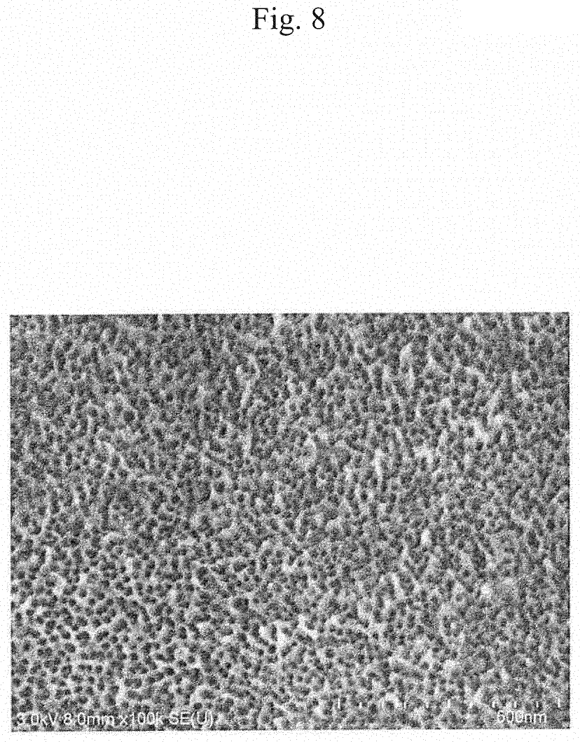

Hereinafter, embodiments of the present invention will be described with reference to FIGS. 1 to 9.

<Configuration of Semiconductor Cooling System in which Member is Incorporated>

FIG. 1 is a schematic diagram illustrating a semiconductor cooling system 100. The semiconductor cooling system 100 includes a cooling unit (heat exchanger) 110, a heat dissipation unit (heat exchanger) 120, a compressor 130, an expansion valve 140, and the like.

The heat dissipation unit 120 includes a heat exchanger 121 and a fan 122, and heat released when the refrigerant is liquefied inside the heat exchanger 121 is released to the outside of the system by the fan 122. The heat exchanger member of the present invention means a member forming the heat exchanger 121. In the following description, the heat exchanger member will be described as a member forming the heat exchanger 121 which is a tube in which the refrigerant is liquefied inside.

<Configuration of Member>

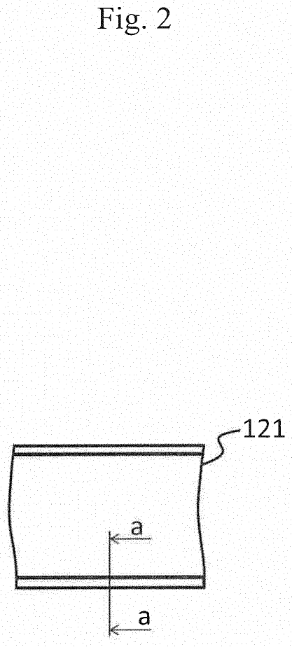

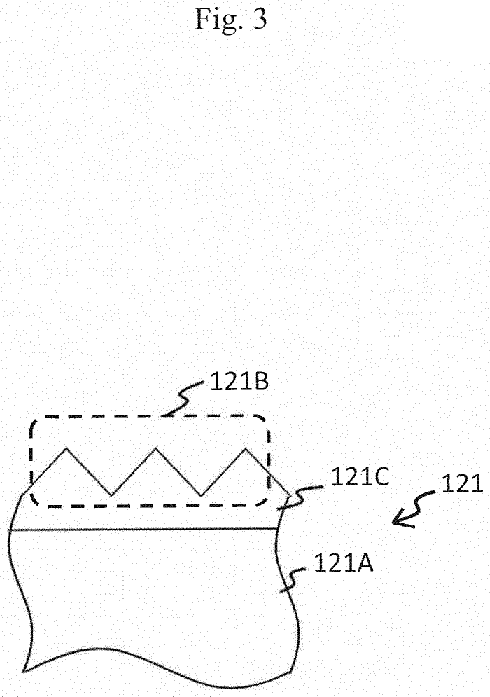

FIG. 2 and FIG. 3, which is a cross-sectional view taken along line a-a in FIG. 2, are views showing a tube forming the heat exchanger 121, which is a specific example of a heat exchanger member of the present invention. As shown in FIG. 3, a crystalline carbon-containing oxide film 121C provided with fine protrusions 121B is provided on a metal base 121A made of a main material (aluminum, stainless steel, copper, etc.) forming a tube. The crystalline carbon-containing oxide film 121C having the fine protrusions 121B as a metal oxide film containing crystalline carbon, and provides a function of enhancing the wettability between the refrigerant and the tube inner surface in contact with the refrigerant in a gas state in the heat, exchanger 121, and enhancing the efficiency of cooling the refrigerant by the high thermal conduction rate of the contained crystalline carbon.

The tube is made of a metal tube such as an aluminum tube, a stainless tube, or a copper tube. The wail thickness and length of the tube are not particularly defined, and are appropriately determined according to the purpose of use.

The crystalline carbon-containing oxide film 121C is an oxide of a metal same as or similar to the metal base material, containing crystalline carbon. The film thickness of the crystalline carbon-containing oxide film 121C may be 10 nm to 300 nm. Furthermore, the film thickness of the crystalline carbon-containing oxide film 121C is preferably 300 nm to 300 nm in order to enhance the liquefaction efficiency by utilizing the thermal conductivity of the contained crystalline carbons. The content ratio of carbon contained in the carbon-containing oxide film 121C may be 5 at % to 50 at % at a point of 3 nm to 5 nm from the surface (the surface opposite to the surface in contact with the metal base 121A). Furthermore, the content ratio of the crystalline carbon contained in the carbon-containing oxide film 121C is preferably 8 at % to 40 at % at a point of 3 nm to 5 nm from the surface in order to provide characteristics given by containing the crystalline carbon and to maintain the strength of the film.

The crystalline carbon contained in the crystalline carbon-containing oxide film 121C is preferably a carbon nanotube, fullerene, graphene, or the like to enhance thermal conduction.

The fine protrusions 121B are provided on the surface of the crystalline carbon-containing oxide film 121C (the surface opposite to the surface in contact with the metal base 121A), and an average spacing between adjacent apexes of the fine protrusions 121B is greater than or equal to 20 nm and less than or equal to 80 nm, an average value of the height of the apexes of the protrusions is greater than or equal to 10 nm and less than or equal to 70 nm, and an aspect ratio which is a value obtained by dividing the average height by the average spacing is less than one.

Furthermore, in order to provide higher wettability to the refrigerant, the fine protrusions 121B more preferably have an average spacing between adjacent apexes of the fine protrusions 121B of greater than or equal to 25 nm and less than or equal to 65 nm, an average value of the height of the apexes of the protrusions of greater than or equal to 15 nm and less than or equal to 55 nm, and an aspect ratio which is a value obtained by dividing the average height by the average spacing of less than 0.83.

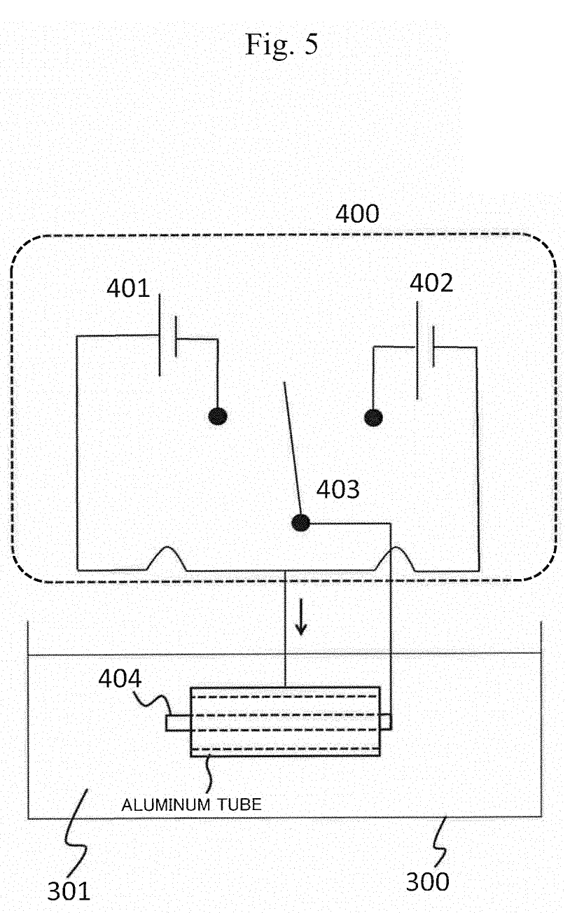

Hereinafter, an example according to the first embodiment will be described with reference to FIGS. 5 to 8. The heat exchanger 121 in the example is manufactured from an aluminum tube having an outer diameter of 9 mm (inner diameter 6 mm)×220 nm. The following treatment was performed in order to provide the crystalline carbon-containing oxide film 121C having the fine protrusions 121B on the inner surface of the aluminum tube (metal base 121A).

First, the aluminum tube (metal base 121A) is immersed and degreased with ethanol (immersion time: 30 minutes). Thereafter, as shown in FIG. 5, the aluminum tube connected to the electric circuit 400 and the SUS 304 electrode 404 connected to the electric circuit 400 in a state of being inserted inside the aluminum tube so as not to contact the inner surface of the aluminum tube are immersed in the bath 300 containing the treatment liquid 301. In the treatment liquid 301 in the bath 300, sodium hydroxide and 0.2% single-walled carbon nanotube dispersion liquid dispersed in purified water by a dispersant are added to purified water so as to have concentrations of 0.35 g/l and 1.35 ml/l, respectively, and the temperature is adjusted so that the liquid temperature becomes 30° C.

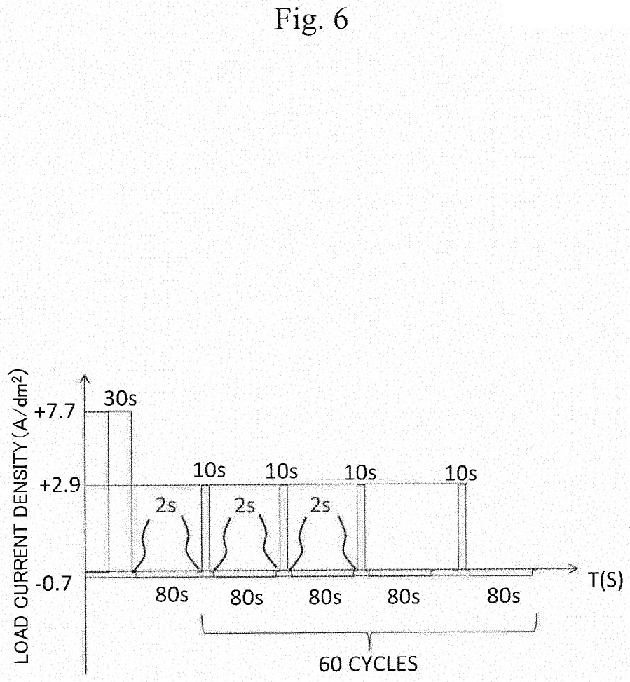

Thereafter, the voltage is loaded on the aluminum tube by a rectifier 401, a rectifier 402, and a changeover switch 403 with the pattern illustrated in FIG. 6, wherein the current flowing in the direction of the arrow illustrated in FIG. 6 is defined as the current in the + direction.

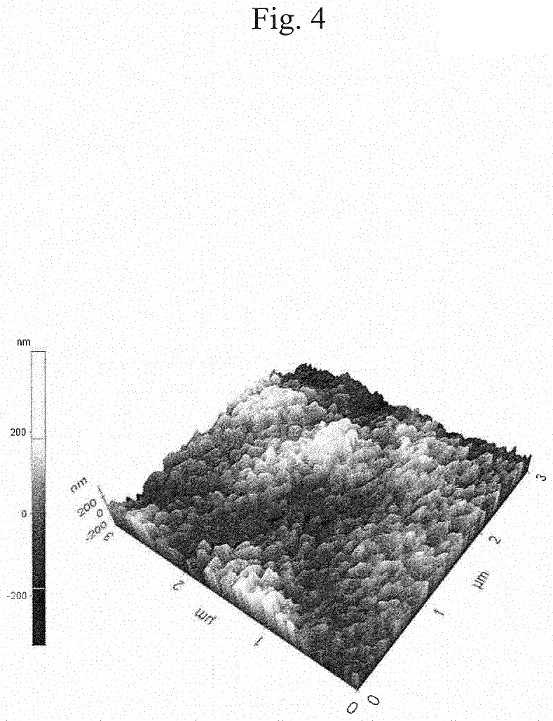

Finally, the aluminum tube is washed with water and dried (80° C. for 30 minutes) in a thermostatic bath. In this way, the crystalline carton-containing oxide film 121C having a thickness of 200 nm is provided on the surface of the aluminum tube (metal base 121A), and at the same time, the fine protrusions 121B having an average spacing between apexes of the adjacent fine protrusions 121B on 61 nm and an average value of heights of the fine protrusions 121B of 50 nm are provided on the surface of the crystalline carbon-containing oxide film 121C (FIG. 4), thereby obtaining the heat exchanger 121.

<Demonstration Test>

Here, characteristics required for the heat exchanger in the heat dissipation unit will be described. The heat exchanger in the heat dissipation unit takes heat from the refrigerant in a gas state that has been vaporized in the cooling unit and has a high temperature and a high pressure through the compressor, and dissipates the heat to the outside, thereby liquefying the refrigerant. At that time, it is necessary to liquefy all the refrigerant so that the refrigerant can circulate through the system. Therefore, if the liquefaction efficiency per unit area with which the refrigerant of the heat exchanger comes into contact is low, the size of the heat exchanger becomes large, which imposes a limitation in the installation of the cooling system and greatly increases the cost.

Furthermore, since the cooling system of the semiconductor generally has a larger heat dissipation unit than a cooling unit, the liquefaction efficiency affects the size and cost of the entire unit. Therefore, it has been required to enhance the liquefaction efficiency in the heat exchanger of the heat dissipation unit.

In the tube forming the heat exchanger of the present invention, the contact angle indicating wettability with the refrigerant (so-called fluorocarbons such as fluorocarbon, a mixture of methylnonafluorobutyl ether and methylnonafluoroisobutyl ether, and the like) can be made very small. For example, in the case of aluminum, the contact angle can be set to 0.67°, from 4.18° when untreated, by adopting the structure according to the present invention, so that the refrigerant is easily flowed and collected. In addition, the structure according to the present invention excels in heat exchangeability because it contains crystalline carbon excelling in thermal conductivity such as carbon nanotubes. Therefore, the heat exchanger of the present invention excels in liquefaction efficiency.

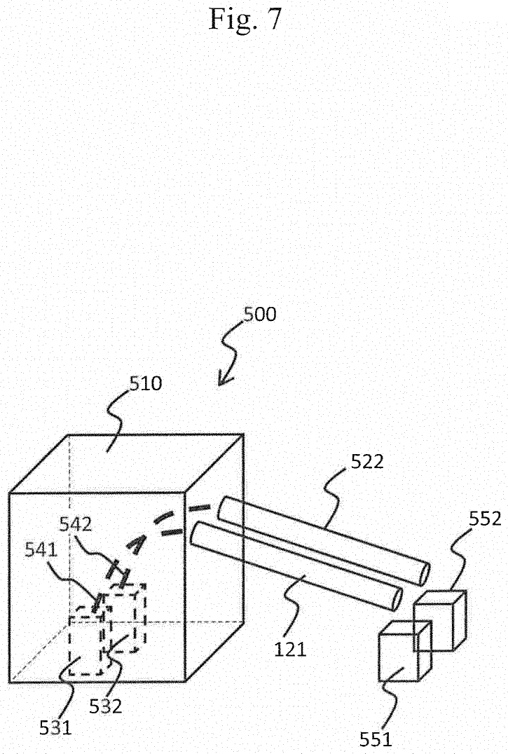

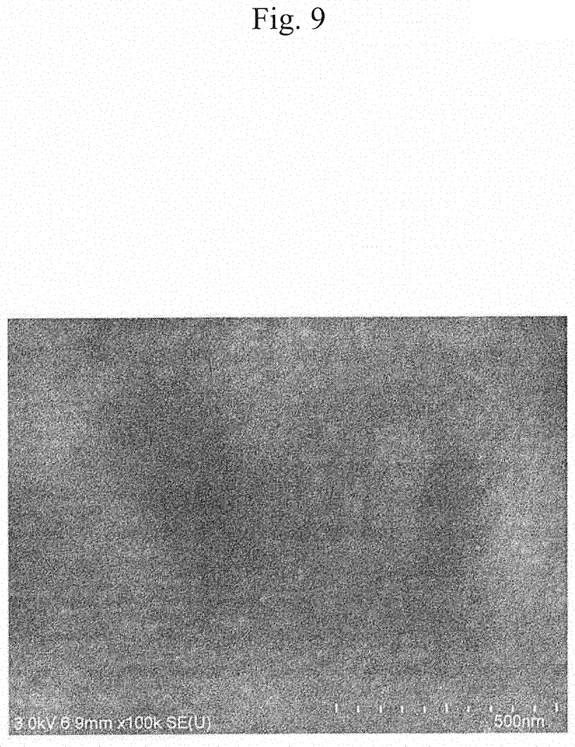

A heat exchanger 121 of the present invention shown in FIGS. 2 to 4 and 8 (contact angle with a refrigerant of 0.67°, 10% content rate of crystalline carbon (at a point of 5 nm from the surface)) and a heat exchanger 522 (contact angle with a refrigerant of 4.18°, 0% content rate of crystalline carbon (at a point of 5 nm from the surface)) which is formed of a comparative untreated aluminum tube having an inner surface as shown in FIG. 9 and having the same shape as that of the present invention are connected to silicon tubes 541 and 542 and installed outside the thermostatic bath 510 as shown in FIG. 7, the silicon tubes 541 and 542 being connected to refrigerant containers 531 and 532 which are installed in a thermostatic bath 510 of a liquefaction characteristic evaluation device 500 shown in FIG. 7 and in which refrigerant is enclosed.

Thereafter, the inside of the thermostatic bath 510 was operated to become 70° C. to evaporate the refrigerant in the refrigerant containers 531 and 532, the vaporized refrigerant was introduced into the heat exchangers 121 and 522, the refrigerant cooled and liquefied at room temperature (15° C.) was collected in the collection containers 551 and 552, the weight of the liquefied refrigerant was measured and divided by the weight of the refrigerant enclosed in the refrigerant containers 531 and 532, respectively, thereby deriving the liquefaction efficiency.

As a result, in the heat exchanger 121 of the present invention, it was confirmed that the liquefaction efficiency became 71.1%, which improved from the liquefaction efficiency 59.8% of the comparative untreated heat exchanger 522.

In the present example, in order to form the crystalline carbon-containing oxide film 121C having the fine protrusions 121B on the surface, a wet electrolytic treatment under the above conditions is used, but the present invention is not limited thereto, and the crystalline carbon-containing oxide film may be formed under other conditions or by other treatment methods (sputtering using a metal oxide target containing carbon nanotubes, sol-gel method, or the like). However, the wet electrolytic treatment is superior to other treatment methods in terms of cost.

As described above, in the heat exchanger 121 (also a heat exchanger member) of the present invention, the size of the entire cooling system can be made smaller than the conventional mechanism in which a mechanism such as the gas-liquid separating unit is added, so that limitation in the installation is reduced. In addition, since a large change is not involved, it is not necessary to change a portion related to the cooling system, so that an increase in cost can be suppressed.

The first embodiment of the present invention is not limited to the pipe-shaped member forming the heat exchanger 121, and may be a member forming a partition wall for cooling a refrigerant provided inside the heat exchanger, a member such as an internal fin, or the like, but in any case, the effect same as the member forming the hear, exchanger 121 is obtained.

In addition, as a matter of course, a heat exchanger including a member forming the heat exchanger 121, a member forming a partition wall for cooling a refrigerant provided inside the heat exchanger, and a member such as an internal fin has the same effect as the heat exchanger 121.

Furthermore, as it is obvious that the cooling system provided with the heat exchanger formed of the members according to the embodiment cf the present invention also exhibits the same effects as those of the heat exchanger 121, the size of the entire cooling system can be reduced, so that limitation in the installation can be reduced. In addition, since a large change is not involved, it is not necessary to change a portion related to the cooling system, so that an increase in cost can be suppressed.

### Second Embodiment

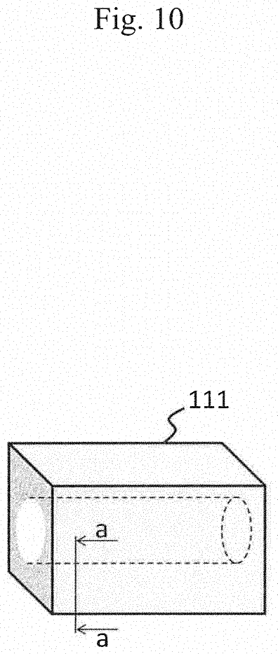

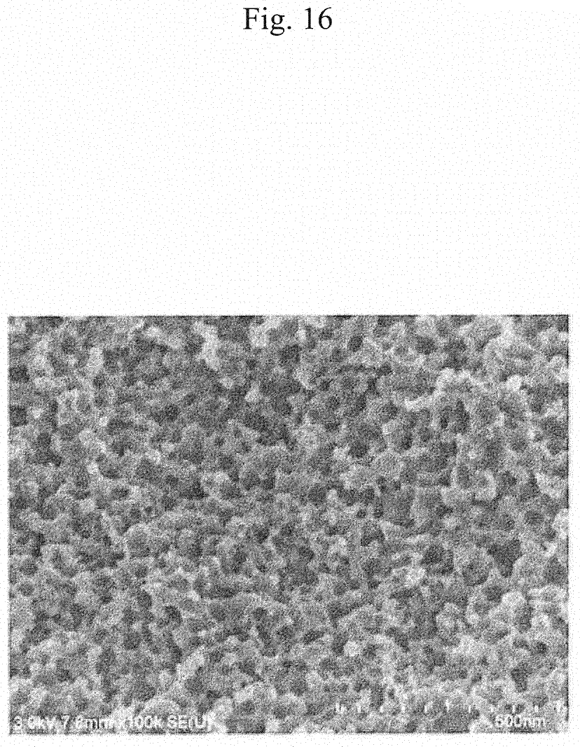

Hereinafter, an embodiment of the present invention will be described with reference to FIGS. 10 to 17.

<Configuration of Semiconductor Cooling System in which Member is Incorporated>

FIG. 1 is a schematic diagram illustrating a semiconductor cooling system 100. The semiconductor cooling system 100 includes a cooling unit 110, a heat, dissipation unit 120, a compressor 130, an expansion valve 140, and the like.

The cooling unit 110 includes a heat exchanger 111 and a semiconductor 150, and the heat generated in the semiconductor 150 is removed when the refrigerant vaporizes inside the heat exchanger 111, so that the semiconductor 150 is cooled. The heat exchanger member of the present invention means a member forming the heat exchanger 111. In the following description, the heat exchanger member will be described as a member forming the heat exchanger 111 which is a tube in which the refrigerant is vaporized inside.

<Configuration of Member>

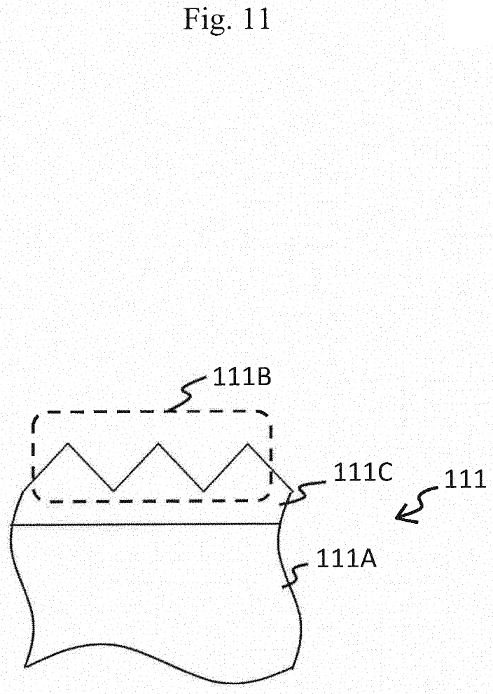

FIG. 19 and FIG. 11, which is a cross-sectional view taken along line a-a in FIG. 10, are views showing a tube forming the heat exchanger 111, which is a specific example of a heat exchanger member of the present invention. As shown in FIG. 11, a crystalline carbon-containing oxide film 111C provided with fine protrusions 111B is provided on a metal base 111A made of a main material (aluminum, stainless steel, copper, etc.) forming a tube. The crystalline carbon-containing oxide film 111C having the fine protrusions 111B is a metal oxide film containing crystalline carbon. In the heat exchanger 111, the crystalline carbon-containing oxide film 111C increases the wettability between the refrigerant and the tube inner surface in contact with the refrigerant in a liquid state, increases the contact area with the refrigerant even when the refrigerant starts to vaporize at the time of cooling, and enhances the thermal conduction rate by the contained crystalline carbon having a high thermal conduction rate, thus providing the function of enhancing the efficiency (vaporization efficiency) of transferring heat transferred from the semiconductor 150 through the heat exchanger 111 to the refrigerant.

The tube is made of a metal tube such as a copper tube, an aluminum tube, or a stainless tube. The wall thickness and length of the tube are not particularly defined, and are appropriately determined according to the purpose of use.

The crystalline carbon-containing oxide film 111C is an oxide of a metal same as or similar to the metal base material, containing crystalline carbon. The film thickness of the crystalline carbon-containing oxide film 111C may be 10 nm to 300 nm. Furthermore, the film thickness of the crystalline carbon-containing oxide film 111C is preferably 100 nm to 300 nm in order to enhance vaporization efficiency (=efficiency of transferring heat from a semiconductor to a refrigerant) by utilizing the thermal conductivity of the contained crystalline carbons. The content ratio of carbon contained in the carbon-containing oxide film 121C may be 5 at % to 50 at % at a point of 3 nm to 5 nm from the surface (the surface opposite to the surface in contact with the metal base 121A). Furthermore, the content ratio of the crystalline carbon contained in the carbon-containing oxide film 121C is preferably 8 at % to 40 at % at a point of 3 nm to 5 nm from the surface in order to provide characteristics given by containing the crystalline carbon and to maintain the strength of the film.

The crystalline carbon contained in the crystalline carbon-containing oxide film 111C is preferably a carbon nanotube, fullerene, graphene, or the like to enhance thermal conduct ion.

The fine protrusions 111B are provided on the surface of the crystalline carbon-containing oxide film 111C (the surface opposite to the surface in contact with the metal base 111A), and an average spacing between adjacent apexes of the fine protrusions 111B is greater than or equal to 20 nm and less than or equal to 80 nm, an average value of the height of the apexes of the protrusions is greater than or equal to 30 nm and less than or equal to 70 nm, and an aspect ratio which is a value obtained by dividing the average height by the average spacing is less than one.

Furthermore, in order to provide higher wettability to the refrigerant, the fine protrusions 111B more preferably have an average spacing between adjacent apexes of the fine protrusions 111B of greater than or equal to 25 nm and less than or equal to 65 nm, an average value of the height of the apexes of the protrusions of greater than or equal to 15 nm and less than or equal to 55 nm, and an aspect ratio which is a value obtained by dividing the average height by the average spacing of less than 0.83.

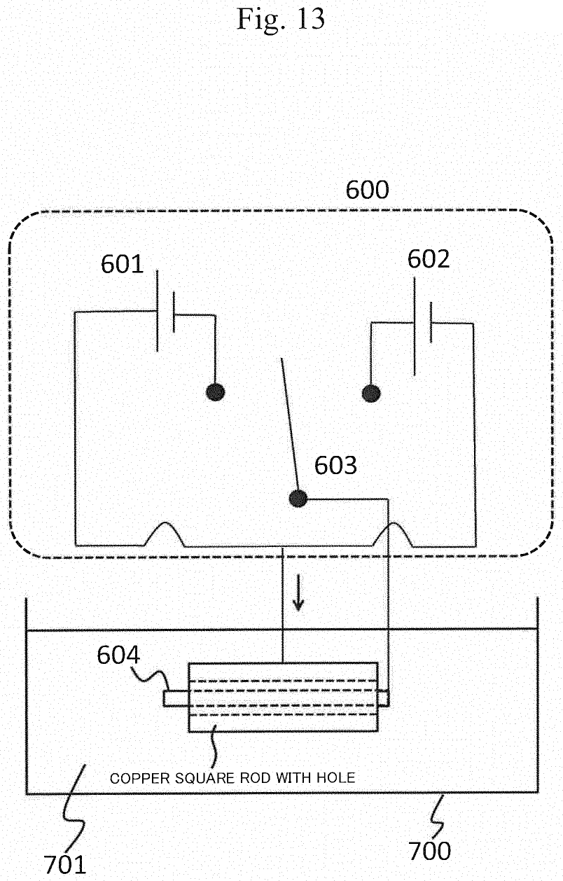

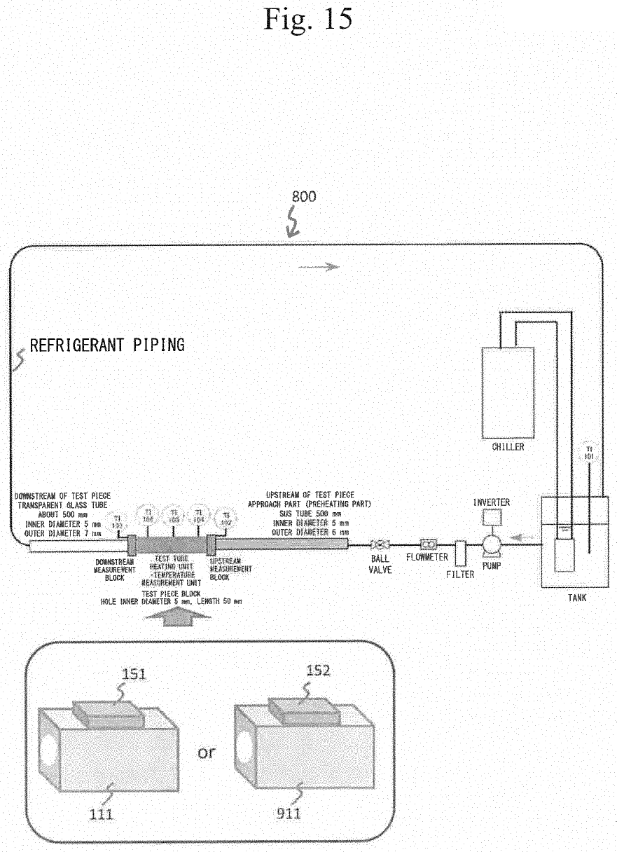

Hereinafter, an example according to the second embodiment will be described with reference to FIGS. 13 to 16. The heat exchanger 111 in the example is manufactured from an 11 mm copper square rod having a length of 50 mm with a through hole of φ5 mm at the center as shown in FIG. 15. The following treatment was performed to provide the crystalline carbon-containing oxide film 111C having the fine protrusions 111B on the surface of the hole of φ5 mm of the copper square rod (metal base 111A).

First, the copper square rod (metal base 111A) is immersed and degreased with ethanol (immersion time: 30 minutes). Thereafter, as shown in FIG. 13, the copper square rod connected to the electric circuit 600 and the SUS 304 electrode 604 connected to the electric circuit 600 in a state of being inserted inside the copper square rod so as not to contact the inner surface of the hole formed in the copper square rod are immersed in the bath 700 containing the treatment liquid 701. In the treatment liquid 701 in the bath 700, sodium hydroxide and 0.2% single-walled carbon nanotube dispersion liquid dispersed in purified water by a dispersant are added to purified water so as to have concentrations of 0.95 g/l and 1.35 ml/l, respectively, and the temperature is adjusted so that the liquid temperature becomes 30° C.

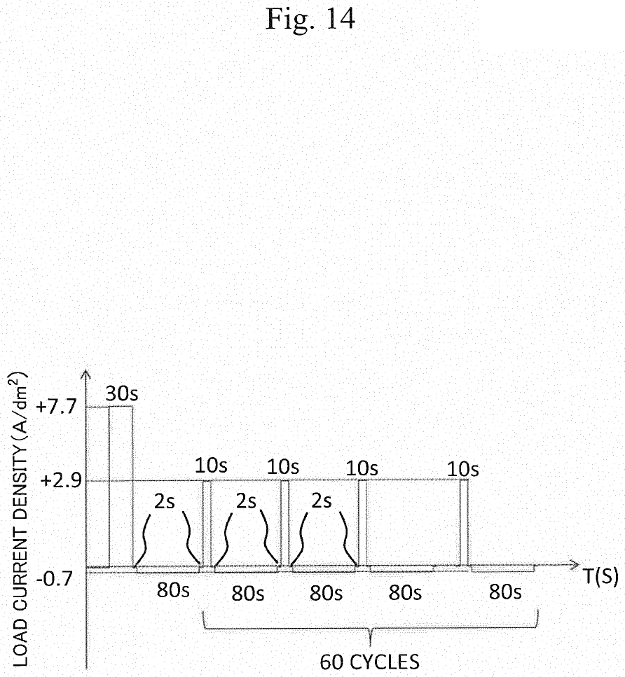

Thereafter, the voltage is loaded on the aluminum tube by a rectifier 601, a rectifier 602, and a changeover switch 603 with the pattern illustrated in FIG. 14, wherein the current flowing in the direction of the arrow illustrated in FIG. 14 is defined as the current in the + direction.

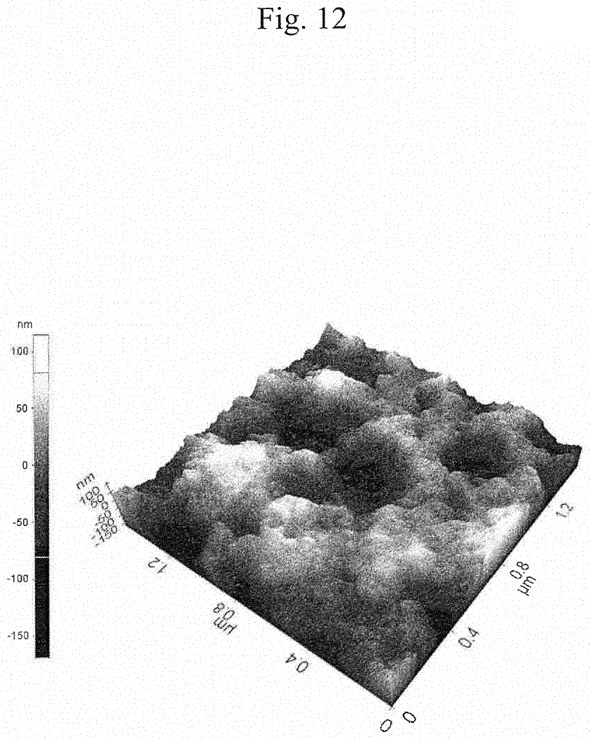

Finally, the copper square rod is washed with water and dried (80° C. for 30 minutes) in a thermostatic bath. In this way, the crystalline carbon-containing oxide film 111C having a thickness of 150 nm is provided on the surface of the copper square rod (metal base 111A), and at the same time, the fine protrusions 111B having an average spacing between apexes of the adjacent fine protrusions 111B of 30.0 nm and an average value of heights of the fine protrusions 111B of 16.4 nm are provided on the surface of the crystalline carbon-containing oxide film 111C (FIG. 12), thereby obtaining the heat exchanger 111.

<Demonstration Test>

Here, characteristics required for the heat exchanger in the cooling unit will be described. In the heat exchanger in the cooling unit, the refrigerant in a liquid state that has been liquefied in the heat dissipation unit and has a low temperature and a low pressure through the expansion valve receives heat generated from a semiconductor to be cooled, and vaporizes, thereby cooling the semiconductor. At that time, if the heat generated in the semiconductor cannot be efficiently taken away, the temperature of the semiconductor rises, and the semiconductor maybe finally destroyed. On the other hand, semiconductors have been increasingly highly integrated in recent years, and therefore the amount of heat generated during the operation is increasing more and more. Therefore, it is necessary to liquefy all the refrigerant so that the refrigerant can circulate through the system that enhances the efficiency of vaporizing the refrigerant to take away heat (hereinafter, referred to as vaporization efficiency). Therefore, if the liquefaction efficiency per unit area with which the refrigerant of the heat exchanger comes into contact is low, the size of the heat exchanger becomes large, which imposes a limitation in the installation of the cooling system and greatly increases the cost.

Furthermore, since the cooling system of the semiconductor generally has a larger heat dissipation unit than a cooling unit, the vaporization efficiency affects the size and cost of the entire unit.

Therefore, in the heat exchanger of the cooling unit, it has been required to increase the efficiency (vaporization efficiency) of vaporizing the refrigerant to take away heat, that is, the heat transfer rate to the refrigerant.

In addition, as high integration progresses further, the heat generated in the semiconductor vaporizes the refrigerant just before the semiconductor, causing a burnout in which cooling is impossible no matter how much refrigerant is flowed, which has been a factor that limits integration of the semiconductor. Therefore, it has been required to increase the critical heat flux at which the burnout occurs, together with the heat transfer rate.

On the inner surface of the hole in the square rod forming the heat exchanger 111 of the present invention, the contact angle indicating wettability with the refrigerant (so-called fluorocarbons such as fluorocarbon, a mixture of methylnonafluorobutyl ether and methylnonafluoroisobutyl ether, and the like) can be mads very small. For example, in the case of copper, the contact angle can be set to 1.77°, from 5.72° when untreated, by adopting the structure according to the present invention, so that the refrigerant and the hole inner surface come into contact with each other over a wider area even when vaporization of the refrigerant starts, and thus heat transfer becomes efficient. In addition, in the structure according to the present invention, the heat exchangeability is further enhanced since crystalline carbon such as carbon nanotubes excelling in thermal conductivity is contained. Therefore, the heat exchanger of the present invention excels in vaporization efficiency (heat transfer rate).

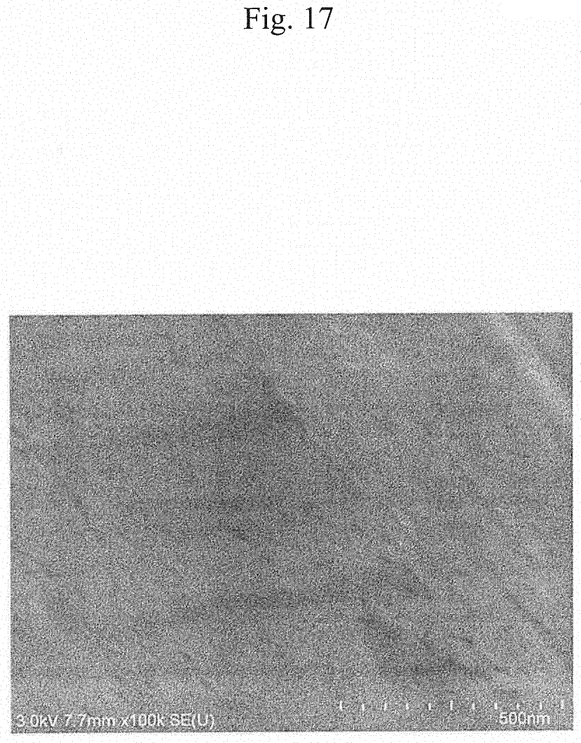

The heat exchanger 111 of the present invention shown in FIGS. 10 to 12 and 16 (contact angle with a refrigerant of 1.77°, 12% content rate of crystalline carbon (at a point of 5 nm from the surface)) and the heat exchanger 911 (contact angle with a refrigerant of 5.72°, 0% content rate of crystalline carbon (at a point of 5 nm from the surface)) which is formed of a comparative untreated copper square rod having an inner surface as shown in FIG. 17 and having the same shape as that of the present invention are alternately installed in the measurement unit of the vaporization characteristic evaluation device 800 shown in FIG. 15, and ceramic heaters 151 or 152 resembling a semiconductor are placed on the upper surface of the installed heat exchangers 111 and 911.

Thereafter, the pump of the vaporization characteristic evaluation device 800 was operated to circulate the refrigerant through the vaporization characteristic evaluation device, and then the output of the ceramic heater was increased to measure the temperature of each unit, thereby deriving the heat transfer rate and the critical heat flux with respect to the refrigerant of the heat, exchanger 111 of the present invention and the comparative untreated heat exchanger 911.

As a result, in the heat exchanger 111 of the present invention, the heat transfer rate was 6.72 W/(m²K) and the critical heat flux was 4.47 W/m², and it was confirmed that both the heat transfer rate and the critical heat flux improved from the heat transfer rate of 5.62 W/(m²K) and the critical heat flux of 4.32 W/m² of the comparative untreated heat exchanger 911.

In the present example, in order to form the crystalline carbon-containing oxide film 111C having the fine protrusions 111B on the surface, a wet electrolytic treatment under the above conditions is used, but the present invention is not limited thereto, and the crystalline carbon-containing oxide film may be formed under other conditions or by other treatment methods (sputtering using a metal oxide target containing carbon nanotubes, sol-gel method, or the like). However, the wet electrolytic treatment is superior to other treatment methods in terms of cost.

As described above, since the heat exchanger 111 (also a heat exchanger member) oi the present invention has an excellent heat transfer rate (vaporization efficiency) as compared with the conventional heat exchanger 911 in which a surface in contact with a refrigerant is untreated, the size of the entire cooling system can be reduced, to that limitation in the installation is reduced. In addition, critical heat flux is improved, so that integration limit of the semiconductors can be improved.

The second embodiment of the present invention is not limited to the square rod shaped member with a hole that forms the heat exchanger 111, and may be a member forming a partition wall for vaporizing a refrigerant provided inside the heat exchanger, a member such as an internal fin, or the like, but in any case, the effect same as the member forming the heat exchanger 111 is obtained.

In addition, as a matter of course, a heat exchanger including a member forming the heat exchanger 111, a member forming a partition wall for vaporizing a refrigerant provided inside the heat exchanger, and a member such as an internal fin has the same effect as the heat exchanger 111.

Furthermore, as it is obvious that the cooling system provided with the heat exchanger formed of the members according to the embodiment of the present invention also exhibits the same effects as those of the heat exchanger 111, the size of the entire cooling system can be reduced, so that limitation in the installation can be reduced. In addition, since a large change is not involved, it is not necessary to change a portion related to the cooling system, so that an increase in cost can be suppressed, and furthermore, integration limit of the semiconductors can be improved.

The inner surface of the member (tube) according to the embodiment of the present invention can reduce the pressure loss when the refrigerant circulates in the cooling system in a state where the liquid and the gas are mixed, and for example, it has been confirmed that when the volume mixing ratio of the gas and the liquid is 30%, the pressure loss can be reduced by 37% as compared with the untreated case by subjecting the inner surface of the stainless tube to the treatment performed in the first and second examples.

Therefore, energy consumption of the pump for circulating the refrigerant can be reduced.

The present invention is not limited to the above-described embodiments, and various modifications can be made within the scope defined in the Claims, where embodiments obtained by appropriately combining technical means disclosed in the different embodiments are also included in the technical scope of the present invention. Furthermore, new technical features can be formed by combining the technical means disclosed in each embodiment.

### INDUSTRYAL APPLICABILITY

The present invention can be used for a heat exchanger member that requires improvement in liquefaction characteristics and/or vaporization characteristics.

### REFERENCE SIGNS LIST

100 semiconductor cooling system

121 heat exchanger (heat dissipation unit)

121A metal base

1218 fine protrusion

121C crystalline carbon-containing oxide film (metal oxide film)

300 bath

400 electric circuit

1. A heat exchanger member made of metal that uses refrigerant, the heat exchanger member being made of metal having a surface that comes into contact with the refrigerant when a heat exchanger formed by the heat exchanger member is operated, the heat, exchanger member comprising:
a metal oxide film provided on the surface, having protrusions, and containing crystalline carbon, wherein
an average spacing between apexes of the protrusions is greater than or equal to 20 nm and less than or equal to 80 nm,
an average value of the height of the apexes of adjacent protrusions is greater than or equal to 10 nm and less than or equal to 70 nm, and
an aspect ratio which is a value obtained by dividing the average height by the average spacing Is less than one.

2. The heat exchanger member according to claim 1, wherein a content ratio of crystalline carbon contained in a range of 3 nm to 5 nm from a surface of the metal oxide film is greater than or equal to 20 at % and less than or equal to 40 at %.

3. The heat exchanger member according to claim 1, wherein the metal oxide film has a thickness of greater than or equal to 100 nm and less than or equal to 300 nm.

4. A heat exchanger comprising the heat exchanger member according to claim 1.

5. A cooling system comprising the heat exchanger according to claim 4.

6. The heat exchanger member according to claim 2, wherein the metal oxide film has a thickness of greater than or equal to 100 nm and less than or equal to 300 nm.

7. A heat exchanger comprising the heat exchanger member according to claim 2.

8. A heat exchanger comprising the heat, exchanger member according to claim 3.

9. A heat exchanger comprising the heat exchanger member according to claim 6.

10. A cooling system comprising the heat exchanger according to claim 7.

11. A cooling system comprising the heat exchanger according to claim 8.

12. A cooling system comprising the heat exchanger according to claim 9.
